(19) United States
(12) Patent Application Publication
(10) Pub. No.: US 2019/0189875 A1
(43) Pub. Date: Jun. 20, 2019

(54) LED FRAME AND MANUFACTURING METHOD THEREOF

(71) Applicant: ECOCERA Optronics Co., Ltd., Taoyuan City (TW)

(72) Inventor: Yu-Jen LIN, Taoyuan City (TW)

(21) Appl. No.: 15/847,056

(22) Filed: Dec. 19, 2017

(51) Int. Cl. H01L 33/62; H01L 33/48; H01L 33/50; H01L 33/60

(52) U.S. Cl. CPC H01L 33/62; H01L 33/486; H01L 33/507; H01L 2933/0066; H01L 2933/0041; H01L 2933/0058; H01L 33/60

(57) ABSTRACT

An LED frame including a ceramic substrate, a copper circuit layer, a copper electrode layer and a gold coating is provided. The copper circuit layer is disposed on a surface of the ceramic substrate. The copper electrode layer covers only a part of the copper circuit layer. The reflective insulation structure covers the other parts of the ceramic substrate and the copper circuit layer, and a top of the reflective insulation structure and a top of the copper electrode layer are arranged coplanar. The gold coating entirely covers a top of the copper electrode layer, the gold coating protrudes from the top of the reflective insulation structure and a border of the gold coating coincides with a border of the copper electrode layer.

### TECHNICAL FIELD

The present disclosure relates to an LED, in particular to an LED frame and a manufacturing method thereof.

### BACKGROUND

An LED chip is too small to be electrically connected to a power supply by bonded conductive wires. Therefore, the LED chip is usually arranged on an LED frame, a circuit is disposed on the LED frame, the circuit includes electrodes for arranging the LED chip thereon, and the LED chip is thereby electrically connected to the power supply. In a conventional process, the circuit and the electrodes are made of copper, and a silver coating is usually electroplated on the electrode in order to effectively electrically connect the LED chip to the electrodes. The silver coating is well conductive and not expensive. The electrodes are arranged in pairs, and a gap between two electrodes of each pair of electrodes is quite narrow. When the LED frame is put into a soldering pot for a welding process, a silver ion migration might occur in the silver coatings of the adjacent electrodes due to a high temperature environment in the soldering pot, and therefore a short circuit is formed in the electrodes. As a result, the LED chip is damaged.

In views of this, in order to solve the above disadvantage, the present inventor studied related technology and provided a reasonable and effective solution in the present disclosure.

### SUMMARY

The present disclosure relates to an LED, in particular to an LED frame and a manufacturing method thereof.

An LED frame including a ceramic substrate, a copper circuit layer, a copper electrode layer and a gold coating is provided in the present disclosure. The copper circuit layer is disposed on a surface of the ceramic substrate. The copper electrode layer covers only a part of the copper circuit layer. The reflective insulation structure covers the other parts of the ceramic substrate and the copper circuit layer, and a top of the reflective insulation structure and a top of the copper electrode layer are arranged coplanar. The gold coating entirely covers a top of the copper electrode layer, the gold coating protrudes from the top of the reflective insulation structure and a border of the gold coating coincides with a border of the copper electrode layer.

According to the LED frame of the present disclosure, a thickness of the copper circuit layer is less than a thickness of the copper electrode layer. A couple of electrodes are formed by the copper electrode layer, a wall surrounding the couple of electrodes is formed on the ceramic substrate and the reflective insulation structure is arranged in a region surrounded by the wall. The wall could be formed by the copper circuit layer. A plurality of circuit blocks separated from each other are defined in the copper circuit layer and at least a part of the wall and the other part of the wall are defined in respective circuit blocks. A plurality of circuit blocks separated from each other are defined in the copper circuit layer, the couple of electrodes are arranged in the respective circuit blocks, and the couple of electrodes are arranged adjacent to and separated from each other. The reflective insulation structure consists of one of silicon dioxide and titanium dioxide.

The LED frame of the present disclosure could further comprise a round cup surrounding the wall.

A manufacturing method of the LED frame is provided in the present disclosure, and the method includes following steps: providing a ceramic substrate; electroplating a copper circuit layer on a surface of the ceramic substrate; electroplating a copper electrode layer on a top of the copper circuit layer, and the copper electrode layer covers only a part of the copper circuit layer; covering an insulation glue on the ceramic substrate; solidifying the insulation glue to form a reflective insulation structure; removing a top of the reflective insulation structure to be coplanar with the top of the copper electrode layer; electroless plating a gold coating on the top of the copper electrode layer, the gold coating entirely covers the top of the copper electrode layer, the gold coating protrudes from the top of the reflective insulation structure and a border of the gold coating coincides with a border of the copper electrode layer.

The reflective insulation structure consists of one of silicon dioxide and titanium dioxide. According to the manufacturing method of the LED frame of the present disclosure, a thickness of the copper circuit layer is less than a thickness of the copper electrode layer. A couple of electrodes are formed by the copper electrode layer, a wall surrounding the couple of electrodes is formed on the ceramic substrate, and the insulation glue is filled in a region surrounded by the wall. The wall is a photoresist structure, and the wall is removed later. A plurality of circuit blocks separated from each other are defined in the copper circuit layer and at least a part of the wall and the other part of the wall are defined in respective circuit blocks. A plurality of circuit blocks separated from each other are defined in the copper circuit layer, the couple of electrodes are arranged in the respective circuit blocks, and the couple of electrodes are arranged adjacent to and separated from each other.

The manufacturing method of the LED frame of the present disclosure could further includes a step: forming a round cup surrounding the wall.

According to the manufacturing method of the LED frame of the present disclosure, a gold coating is electroless plated on the top of the copper electrode layer, the gold coating is chemically more stable the conventional silver coating, and an electroless plating process costs less than an electroplating process.

### BRIEF DESCRIPTION OF DRAWING

The present disclosure can be more fully understood by reading the following detailed description of the embodiment, with reference made to the accompanying drawings as follows:

FIG. 1 is a flow chart showing steps of the manufacturing method of the LED frame according to an embodiment of the present disclosure.

FIGS. 2 to 7 are schematic views showing the respective steps of the manufacturing method of the LED frame according to the embodiment of the present disclosure.

FIGS. 8 to 9 are schematic views showing various usage of the LED frame according to the embodiment of the present disclosure.

FIGS. 10 to 12 are schematic views showing the respective steps of the manufacturing method of the LED frame of the present disclosure for manufacturing another LED frame.

### DETAILED DESCRIPTION

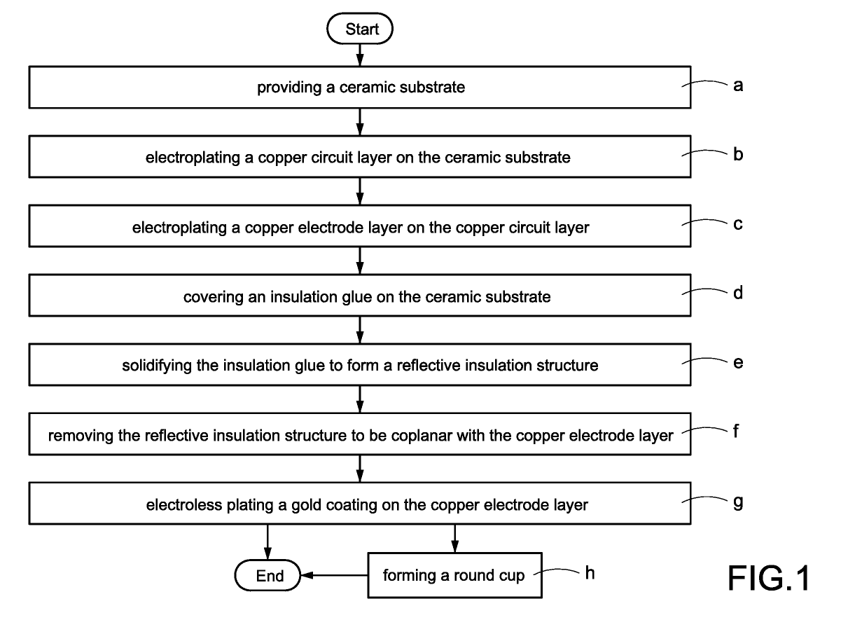

According to FIG. 1, a manufacturing method of an LED frame is provided in an embodiment of the present disclosure, and the method includes following steps.

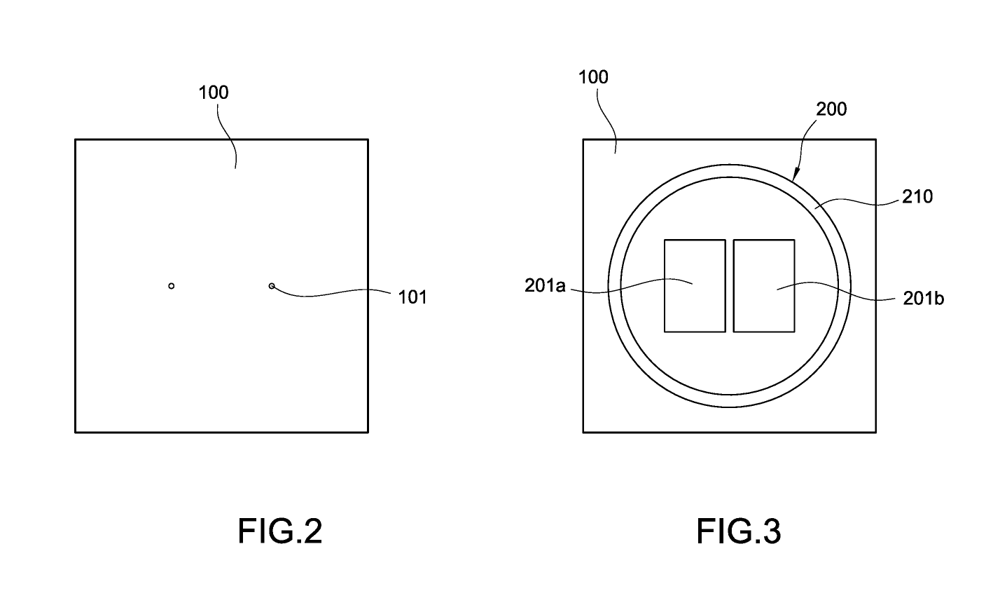

According to FIGS. 1 and 2, firstly, a ceramic substrate 100 provided in step a.

According to FIGS. 1 and 3, in step b following step a, a copper circuit layer 200 is electroplated on at least a surface of the ceramic substrate 100, a through hole 101 could be defined on the ceramic substrate 100 and for the copper circuit layer 200 is allowed to attach on an internal surface of the through hole 101 if the copper circuit layer 200 is disposed on respective surfaces of the ceramic substrate 100, and he respective parts of the copper circuit layer 200 disposed on two surfaces of the ceramic substrate 100 are thereby electrically connected with each other. According to the present step, a wall 210 surrounding the other parts of the copper circuit layer 200 is formed by an outer part of the copper circuit layer 200. However, scope of the present disclosure should not be limited to the embodiment, the wall 210 alternatively could be formed by a photoresist structure further arranged on the ceramic substrate 100. Multiple circuit blocks 201a/201b separated from each other are defined in the copper circuit layer 200, and everywhere in each circuit block 201a/201b are electrically connected with each other, and the circuit blocks 201a/201b are separated and insulated from each other.

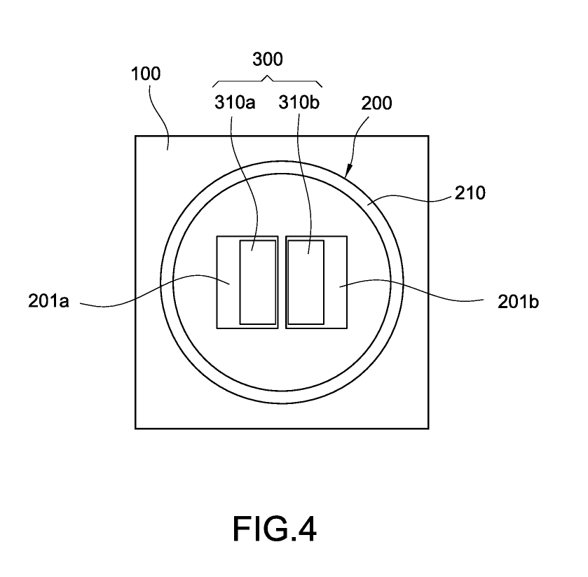

According to FIGS. 1 and 4, in step c following step b, a copper electrode layer 300 is electroplated on top of the copper circuit layer 200, the copper electrode layer 300 covers only a part of the copper circuit layer 200, and a thickness of the copper circuit layer 200 is less than a thickness of the copper electrode layer 300. A couple of electrodes 310a/310b are formed by the copper electrode layer 300, and this couple of electrodes 310a/310b are surrounded by the aforementioned wall 210. The respective electrodes 310a/310b of this couple of electrodes 310a/310b are defined in the respective circuit block 201a/201b, and this couple of electrodes 310a/310b are arranged adjacent to and separated from each other.

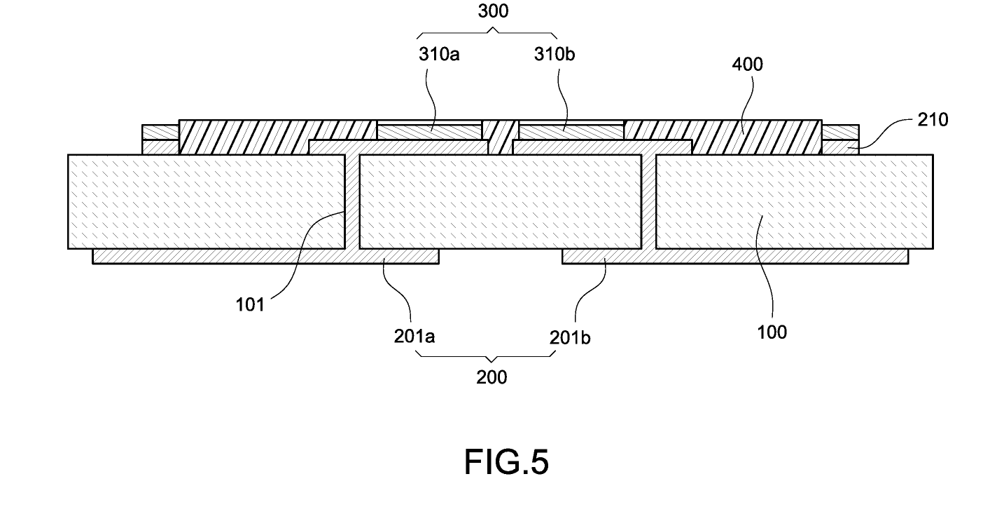

According to FIGS. 1 and 5, in step d following step c, ceramic substrate 100 is covered by an insulation glue the, and the insulation glue consists one of silicon dioxide and titanium dioxide. The other parts of the copper circuit layer 200 are covered by the glue; and the insulation glue is filled in a region surrounded by the wall 210.

In step e following step d, solidifying the insulation glue to form a reflective insulation structure 400, the means of solidifying is not limited in the present disclosure, the means could be drying to solidify, heat curing, UV curing. The reflective insulation structure 400 consists of one of silicon dioxide and titanium dioxide and thereby well reflective and could be used for not only insulation between the circuit blocks 201a/201b, but also reflecting lights.

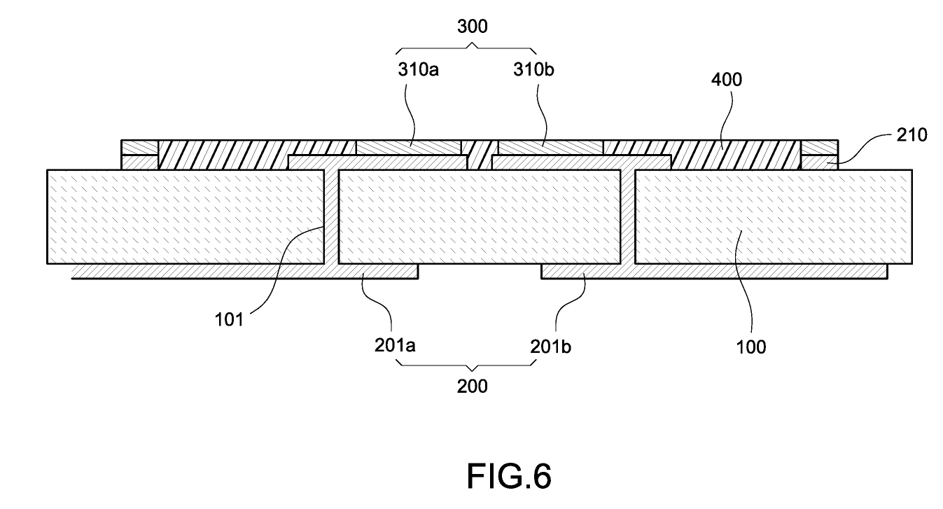

According to FIGS. 1 and 6, in step f following step e, removing a top of the reflective insulation structure 400 to be coplanar with the top of the copper electrode layer 300, the means of removing the top of the reflective insulation structure 400 is not limited in the present disclosure, the means could be planning or polishing.

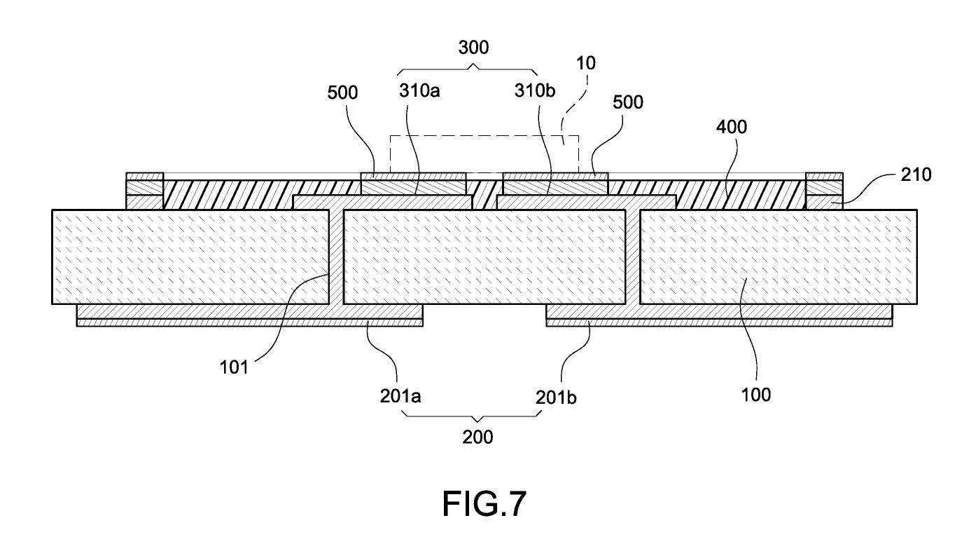

According to FIGS. 1 and 7, in step g following step f, the copper electrode layer 300 is immersed into a plating solution including gold ion, and a gold coating 500 is thereby electroless plated on the top of the copper electrode layer 300 by process. Copper electrode layer 300 is exposed and completely uncovered, the gold ions in the plating solution only attach on metal surfaces, and the gold coating 500 therefore completely covers the copper electrode layer 300 and a border of the gold coating 500 coincides with a border of the copper electrode layer 300, namely an LED frame made by the method of the present disclosure includes a feature that a region of the gold coating 500 coincides with a region of the copper electrode layer 300. Furthermore, the top of the reflective insulation structure 400 is arranged coplanar with the top of the copper electrode layer 300, and the gold coating 500 therefore protrudes from the top of the reflective insulation structure 400. The wall 210 formed by the copper circuit layer 200 or the photoresist structure could be removed in this step.

According to FIG. 7, an LED chip 10 is allowed to arranged on the couple of electrodes 310a/310b of the LED frame made by the manufacturing method of the present disclosure, the LED chip 10 is arranged across between the couple of electrodes 310a/310b, the LED chip 10 is driven to illuminate by different voltages loaded on the respective circuit blocks 201a/201b where the electrodes 310a/310b is located because the respective electrodes 310a/310b of the couple of electrodes 310a/310b are arranged in the respective circuit blocks 201a/201b.

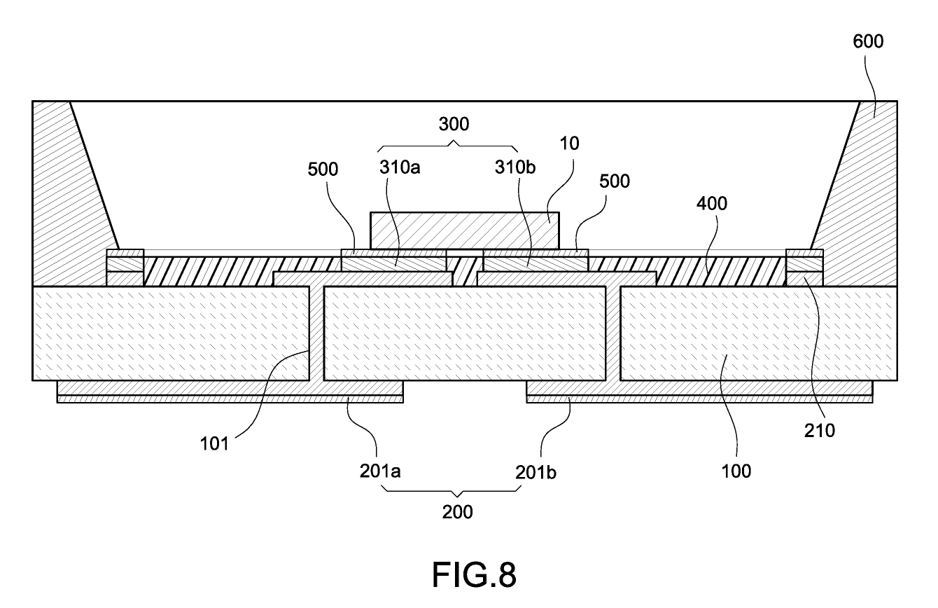

According to the present embodiment shown in FIG. 8, the manufacturing method of the LED frame of the present disclosure could alternatively further include a step h following the step g: forming a round cup 600 surrounding the wall 210 for containing a color fluorescent glue.

According to the present embodiment shown in FIG. 7, the LED frame made by the manufacturing method of LED frame of the present disclosure is detailly described below. The LED frame of the present disclosure includes a ceramic substrate 100, a copper circuit layer 200, a copper electrode layer 300 and a gold coating 500. The copper circuit layer 200 is disposed on a surface of the ceramic substrate 100, a wall 210 is formed by the copper circuit layer 200 and multiple circuit blocks 201a/201b separated from each other are defined in the copper circuit layer 200. The copper electrode layer 300 covers only a part of the copper circuit layer 200 and a thickness of the copper circuit layer 200 is less than a thickness of the copper electrode layer 300, a couple of electrodes 310a/310b are formed by the copper electrode layer 300, the couple of electrodes 310a/310b are surrounded by the wall 210, the respective electrodes 310a/310b of the couple of electrodes 310a/310b are arranged in respective circuit blocks 201a/201b, the couple of electrodes 310a/310b are arranged adjacent to and separated from each other. The reflective insulation structure 400 is located in a region surrounded by the wall 210, and the reflective insulation structure 400 covers the ceramic substrate and the other parts of the copper circuit layer 200, the top of the reflective insulation structure 400 and the top of the copper electrode layer 300 are arranged coplanar. The gold coating 500 completely covers the copper electrode layer 300, the gold coating 500 protrudes from the top of the reflective insulation structure 400 and a border of the gold coating 500 coincides with a border of the copper electrode layer 300, the reflective insulation structure 400 consists of one of silicon dioxide and titanium dioxide and is therefore used for not only for insulation between the circuit blocks 201a/201b but also reflecting lights.

According to FIG. 8, the LED frame of the present disclosure, could alternatively further include a round cup 600 surrounding the wall 210. The color fluorescent glue could be filled in the round cup 600 to filter specific color lights of the LED chip 10.

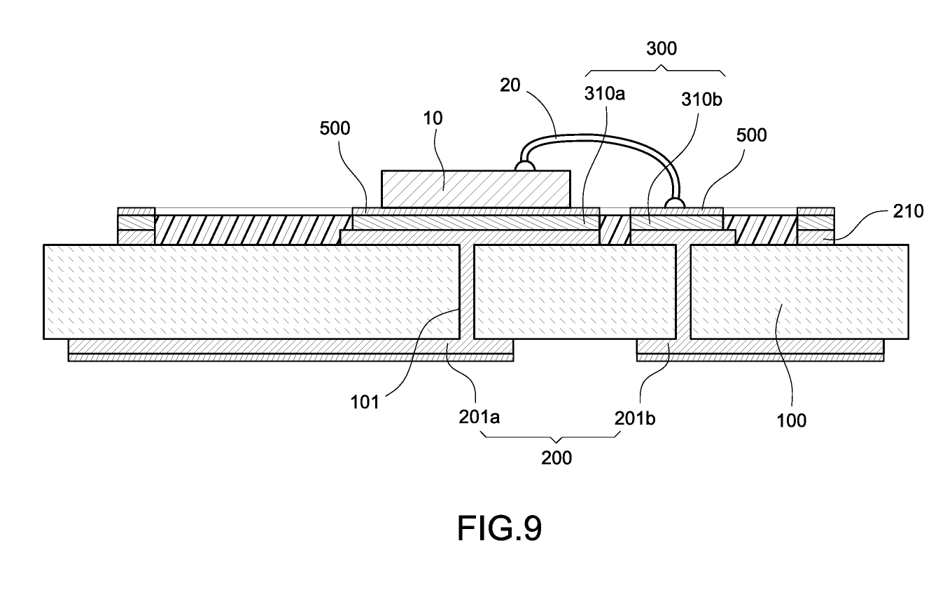

According to the present embodiment shown in FIGS. 7 and 8, the LED chip 10 could be arranged across between the corresponding couple of electrodes 310a/310b, the LED chip 10 is contacted with the respective gold coatings 500 on the respective corresponding electrodes 310a/310b and thereby electrically connected with the respective corresponding electrodes 310a/310b. According to FIG. 9, the LED chip 10 could be alternatively arranged on one of the corresponding electrodes 310a, and electrically connected with the other electrode 310b by a bonded wire 20.

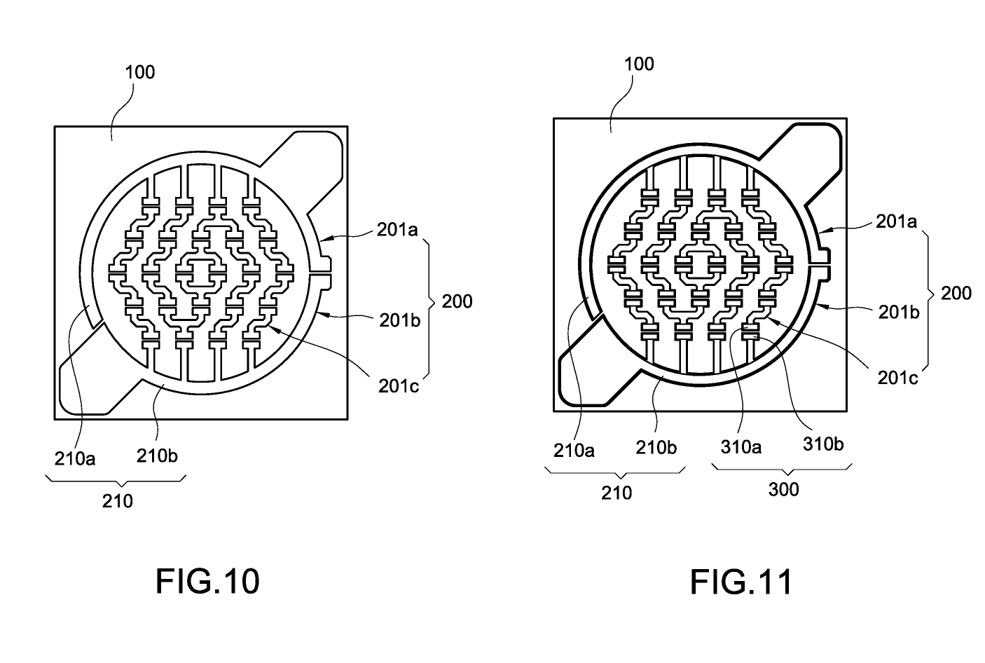

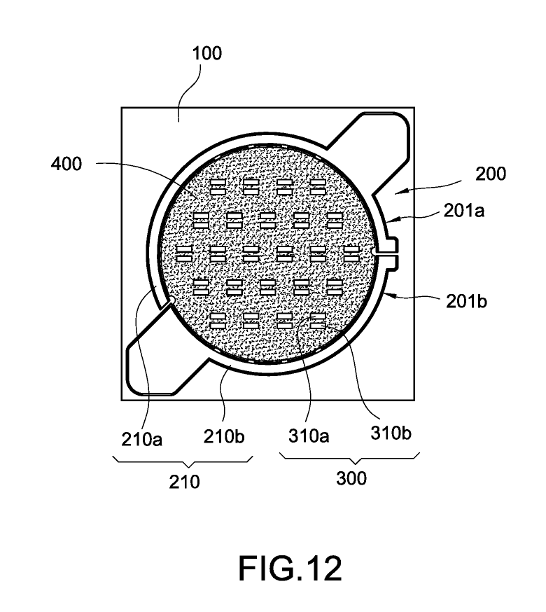

According to FIGS. 10 to 12, an LED frame made by the manufacturing method of LED frame of the aforementioned embodiment is provided in another embodiment of the present disclosure. The difference between the present embodiment and the aforementioned embodiment is that multiple couples of electrodes 310a/310b are formed in the copper electrode layer 300.

Multiple circuit blocks 201a/201b/201c separated from each other are formed in the copper circuit layer 200 and at least a part of the wall 210a and the other parts of the wall 210b are formed in respective circuit blocks 201a/201b, the respective electrodes 310a/310b of each couple are located in the respective circuit blocks 201a/201b/210c. Therefore, the respective aforementioned walls 210 separated from each other are formed in the respective circuit blocks 201a/201b for electrically connecting with one of the electrodes 310a/310b to constitute a parallel circuit. Voltage sources with different electric potentials are load on the two parts of wall 210a/210b to generate a voltage difference on each couple of electrodes 310a/310b.

According to the manufacturing method of LED frame of the present disclosure, the gold coating 500 is electroless plated on the top of the copper electrode layer 300, the gold coating 500 is chemically more stable than a conventional electroplated silver coating and therefore able to withstand high temperature environment in welding operation, and an electroless plating operation cost much less than an electroplating operation. The LED frame made by the manufacturing method of LED frame of the present disclosure includes a feature that a region of the gold coating 500 coincides a region of the copper electrode layer 300.

According to conventional operation, a mask should be arranged to cover the other parts of the copper electrode layer 300 before plating if the gold coating 500 is formed on a part of a region of the copper electrode layer 300; the mask should be arranged and a seed layer should be further arranged on the top of the reflective insulation structure 400 to allow gold ions to attach on the reflective insulation structure 400 if the gold coating 500 exceeds the region of the copper electrode layer 300 and covers a part of the reflective insulation structure 400. Therefore, the conventional operation of plating gold is complex and expensive.

Although the present disclosure has been described with reference to the foregoing preferred embodiment, it will be understood that the disclosure is not limited to the details thereof. Various equivalent variations and modifications can still occur to those skilled in this art in view of the teachings of the present disclosure. Thus, all such variations and equivalent modifications are also embraced within the scope of the present disclosure as defined in the appended claims.

What is claimed is:

1. An LED frame, comprising:
a ceramic substrate;
a copper circuit layer disposed on a surface of the ceramic substrate;
a copper electrode layer, the reflective insulation structure covering only a part of the copper circuit layer;
a reflective insulation structure covering the rest parts of the ceramic substrate and the copper circuit layer, a top of the reflective insulation structure and a top of the copper electrode layer being arranged coplanar; and
a gold coating entirely covering a top of the copper electrode layer, the gold coating protruding from the top of the reflective insulation structure, a border of the gold coating coinciding with a border of the copper electrode layer.

2. The LED frame according to claim 1, wherein a thickness of the copper circuit layer is less than a thickness of the copper electrode layer.

3. The LED frame according to claim 1, wherein a couple of electrodes are formed by the copper electrode layer, a wall surrounding the couple of electrodes is formed on the ceramic substrate and the reflective insulation structure is arranged in a region surrounded by the wall.

4. The LED frame according to claim 3, wherein the wall is formed by the copper circuit layer.

5. The LED frame according to claim 4, wherein a plurality of circuit blocks separated from each other are defined in the copper circuit layer and at least a part of the wall and the other part of the wall are defined in respective circuit blocks.

6. The LED frame according to claim 4, wherein a plurality of circuit blocks separated from each other are defined in the copper circuit layer, the couple of electrodes are arranged in the respective circuit blocks, and the couple of electrodes are arranged adjacent to and separated from each other.

7. The LED frame according to claim 1, wherein the reflective insulation structure consists of one of silicon dioxide and titanium dioxide.

8. The LED frame according to claim 1, further comprises a round cup surrounding the wall.

9. A manufacturing method of an LED frame, comprising following steps:
a) providing a ceramic substrate;
b) electroplating a copper circuit layer on a surface of the ceramic substrate;
c) electroplating a copper electrode layer on a top of the copper circuit layer, wherein the copper electrode layer covers only a part of the copper circuit layer;
d) covering an insulation glue on the ceramic substrate;
e) solidifying the insulation glue to form a reflective insulation structure;
f) removing a top of the reflective insulation structure to be coplanar with the top of the copper electrode layer; and
g) electroless plating a gold coating on the top of the copper electrode layer, wherein the gold coating entirely covers the top of the copper electrode layer, the gold coating protrudes from the top of the reflective insulation structure and a border of the gold coating coincides with a border of the copper electrode layer.

10. The manufacturing method of the LED frame according to claim 9, wherein a thickness of the copper circuit layer is less than a thickness of the copper electrode layer.

11. The manufacturing method of the LED frame according to claim 9, wherein a couple of electrodes are formed by the copper electrode layer, a wall surrounding the couple of electrodes is formed on the ceramic substrate, and the insulation glue is filled in a region surrounded by the wall.

12. The manufacturing method of the LED frame according to claim 11, wherein the wall is a photoresist structure and the wall is removed in step f.

13. The manufacturing method of the LED frame according to claim 11, wherein the wall is formed by the copper circuit layer.

14. The manufacturing method of the LED frame according to claim 13, wherein the wall is removed in step f.

15. The manufacturing method of the LED frame according to claim 9, wherein a couple of electrodes are formed by the copper electrode layer, a wall surrounding the couple of electrodes is formed by the copper circuit layer, and the insulation glue is filled in a region surrounded by the wall.

16. The manufacturing method of the LED frame according to claim 15, wherein a plurality of circuit blocks separated from each other are defined in the copper circuit layer and at least a part of the wall and the other part of the wall are defined in respective circuit blocks.

17. The manufacturing method of the LED frame according to claim 15, wherein a plurality of circuit blocks separated from each other are defined in the copper circuit layer, the couple of electrodes are arranged in the respective circuit blocks, and the couple of electrodes are arranged adjacent to and separated from each other.

18. The manufacturing method of the LED frame according to claim 9, wherein the reflective insulation glue consists one of silicon dioxide and titanium dioxide.

19. The manufacturing method of the LED frame according to claim 9, further comprises a step: forming a round cup surrounding the wall.
